(19) United States
(12) Patent Application Publication
(10) Pub. No.: US 2011/0193110 A1
(43) Pub. Date: Aug. 11, 2011

(54) LIGHT EMITTING DIODE ILLUMINATING APPARATUS WITH SAME-TYPE LIGHT EMITTING DIODES

(75) Inventors: CHUNG-MIN CHANG, HuKou (TW); CHIH-PENG HSU, HuKou (TW); CHUN-WEI WANG, HuKou (TW)

(73) Assignee: ADVANCED OPTOELECTRONIC TECHNOLOGY, INC., Hsinchu Hsien (TW)

(21) Appl. No.: 13/089,230

(22) Filed: Apr. 18, 2011

Related U.S. Application Data
(62) Division of application No. 12/488,715, filed on Jun. 22, 2009.

(30) Foreign Application Priority Data
Jul. 1, 2008 (CN) 200810302484.X

(51) Int. Cl. H01L 33/52

(52) U.S. Cl. 257/89; 257/E33.059

(57) ABSTRACT

A light emitting diode illuminating apparatus includes a substrate, a first lighting element and a second lighting element. The first and second lighting elements are juxtaposed at the substrate. The first lighting element includes a first LED chip, and a first filling layer encapsulating the first LED chip. The first filling layer includes red phosphor generally evenly doped therein. The second lighting element includes a second LED chip and a second filling layer encapsulating it. The second filling layer includes two different phosphor materials respectively doped therein. The first LED chip and the second LED chip are the same kind of LED chip selected from the group consisting of GaN LED chips, AlGaN LED chips and InGaN LED chips. Light emitted from the first filling layer and the second filling layer is capable of mixing to produce light of a uniform color.

### CROSS-REFERENCE TO RELATED APPLICATIONS

The present application is a divisional application of U.S. patent application Ser. No. 12/488,715, filed on Jun. 22, 2009, which is based on and claims priority from Chinese Patent Application No. 200810302484.X, filed in China on Jul. 1, 2008. The entire contents of the aforementioned related applications are incorporated by reference herein.

### BACKGROUND

1. Technical Field

The disclosure generally relates to solid-state illuminating apparatuses, and particularly, to a light emitting diode illuminating apparatus having an improved color temperature stability of the emitting light.

2. Description of Related Art

Light emitting diodes (LEDs) as solid-state illuminating apparatuses are widely used in illumination applications. LEDs are promising candidates to substitute conventional fluorescent lamps, due to their high brightness, long service lifetime, and wide color gamut. These and related issues are discussed in an article entitled “Solid-State Lighting: Toward Superior Illumination” by Michael S. Shur et al., published in Proceedings of the IEEE, Vol. 93, No. 10, in October, 2005.

Generally, an LED lighting source is expected to have a high color rendering index (CRI), typically as high as CRI>90. A typical LED with a high CRI includes a blue LED chip, a red LED chip, and an encapsulant encapsulating the blue LED chip and the red LED chip therein. The encapsulant has a yellow phosphor material doped therein.

Generally, a blue LED chip is substantively different from a red LED chip. For example, the blue LED chip may be a gallium nitride (GaN) LED chip and the red LED chip may be an aluminum gallium indium phosphide (AlGaInP) LED chip. Thus, when temperatures of the blue LED chip and the red LED chip rise, the light attenuation of the blue LED chip is different from that of the red LED chip. Generally, the light attenuation of the red LED chip is greater than that of the blue LED chip, resulting in the color temperature of the mixed light emitted from the LED exhibiting a blue shift. In addition, the stability of the color temperature is liable to be unsatisfactory with changes in the elevated temperatures of the blue LED chip and the red LED chip.

What is needed, therefore, is a light emitting diode illuminating apparatus which can overcome the above-mentioned disadvantages.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic cross-section of a first embodiment of a light emitting diode illuminating apparatus.

FIG. 2 is a schematic cross-section of a second embodiment of a light emitting diode illuminating apparatus.

FIG. 3 is a schematic cross-section of a third embodiment of a light emitting diode illuminating apparatus.

FIG. 4 is a schematic cross-section of a fourth embodiment of a light emitting diode illuminating apparatus.

FIG. 5 is a schematic cross-section of a fifth embodiment of a light emitting diode illuminating apparatus.

FIG. 6 is a schematic cross-section of a sixth embodiment of a light emitting diode illuminating apparatus.

FIG. 7 is a schematic cross-section of a seventh embodiment of a light emitting diode illuminating apparatus.

### DETAILED DESCRIPTION

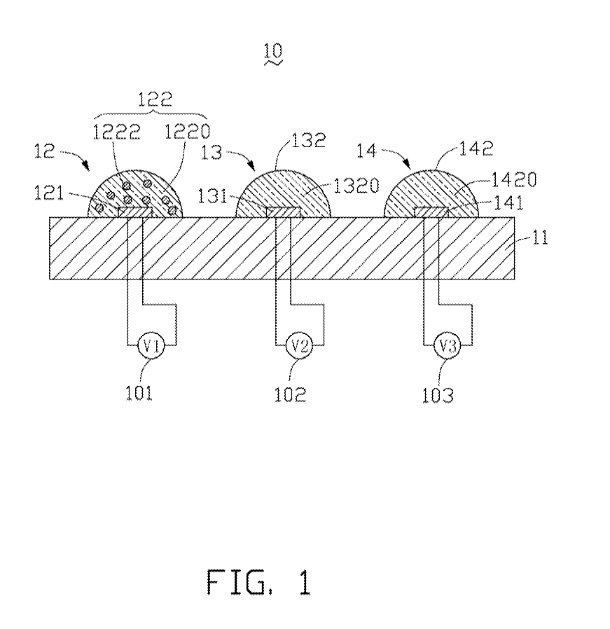

Referring to FIG. 1, a first embodiment of a light emitting diode illuminating apparatus 10 includes a substrate 11, a first lighting element 12, a second lighting element 13, and a third lighting element 14.

The first lighting element 12, the second lighting element 13, and the third lighting element 14 are positioned on the substrate 11 in a juxtaposed manner The substrate 11 may be connected to a power source (not shown) to supply electric current to the first lighting element 12, the second lighting element 13, and the third lighting element 14. In addition, heat generated from the first lighting element 12, the second lighting element 13, and the third lighting element 14 can be conducted out of the light emitting diode illuminating apparatus 10 through the substrate 11. The substrate 11 may be made of metal such as copper or aluminum, ceramic such as silicon nitride, aluminium oxide, or beryllium oxide, or silicon. It can be understood that the substrate 11 may be ceramic aluminum substrate.

The first lighting element 12 includes a first light emitting diode chip (LED chip) 121, and a first filling layer 122 encapsulating the first LED chip 121. The second lighting element 13 includes a second LED chip 131, and a second filling layer 132 encapsulating the second LED chip 131. The third lighting element 14 includes a third

LED chip 141, and a third filling layer 142 encapsulating the third LED chip 141. The first, second, and third LED chips 121, 131, and 141 are electrically connected to the substrate 11.

Preferably, all of the first LED chip 121, the second LED chip 131, and the third LED chip 141 are the same kind of LED chip. For example, all of the first, second and third LED chips 121, 131, and 141 can be GaN LED chips, or aluminum gallium nitride (AlGaN) LED chips, or indium gallium nitride (InGaN) LED chips. Thus, temperature-dependent light attenuation of the first LED chip 121 is essentially the same as that of the second LED chip 131 and the third LED chip 141. As a result, color temperature of white light emitted from the light emitting diode illuminating apparatus 10 is stable, and luminous efficiency of the LED chips 121, 131, 141 are also stable.

In the present embodiment, the first LED chip 121 and the second LED chip 131 are green LED chips, which can emit green light having a center wavelength in a range from 505 nm to 540 nm. The green LED chips may be GaN LED chips or InGaN LED chips. The third LED chip 141 is a blue LED chip, which can emit blue light having a center wavelength in a range from 445 nm to 475 nm. The blue LED chip is typically a GaN LED chip. The first, second and third LED chips 121, 131, and 141 are electrically connected to a first power supply 101, a second power supply 102, and a third power supply 103, respectively. The first, second and third LED chips 121, 131, and 141 each include a separate driving circuit. That is, voltages and currents in the first, second and third LED chips 121, 131, and 141 are independently controlled by the first power supply 101, the second power supply 102, and the third power supply 103, respectively.

The first filling layer 122 includes a first transparent material 1220, and a first phosphor 1222 generally evenly doped in the first transparent material 1220. The first transparent material 1220 may be silicone, resin, or another suitable light-pervious material. In the present embodiment, the first transparent material 1220 includes silicone with a refractive index larger than 1.4. The first phosphor 1222 is red phosphor, and can be excited by excitation light generated from the first LED chip 121 to emit red light. A center wavelength of the red light is in a range from 610 nm to 645 nm. The red phosphor can be made of nitride, silicate, oxide, or sulfide.

The second filling layer 132 includes a second transparent material 1320. The second transparent material 1320 may be silicone, resin, or another suitable light-pervious material.

The third filling layer 142 includes a third transparent material 1420. The third transparent material 1420 may be silicone, resin, or another suitable light-pervious material.

The first phosphor 1222 doped in the first transparent material 1220 is excited by the green light generated from the first LED chip 121 to emit red light, and a part of the green light generated from the first LED chip 121 can be emitted from the first filling layer 122 through the first transparent material 1220. The green light generated from the second LED chip 131 can be emitted from the second filling layer 132. The blue light generated from the blue LED chip 141 can be emitted from the third filling layer 142. The currents flowing through the first LED chip 121, the second LED chip 131, and the third LED chip 141 are controlled independently by the first power supply 101, the second power supply 102, and the third power supply 103, respectively, to adjust the color temperature of the red light and green light emitting from the first filling layer 122, the green light emitting from the second filling layer 132, and the blue light emitting from the third filling layer 142. Thus, the light output by the light emitting diode illuminating apparatus 10 is formed by a mixture of the red light, the green light and the blue light. Such outputted light can create different colors and/or different CRIs to meet different needs.

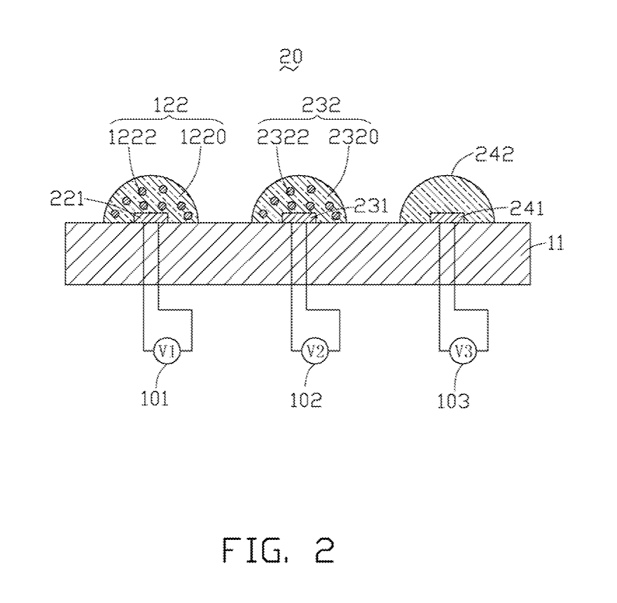

Referring to FIG. 2, a second embodiment of a light emitting diode illuminating apparatus 20 is similar to the first embodiment of the light emitting diode illuminating apparatus 10 except as follows:

A first LED chip 221, a second LED chip 231, and a third LED chip 241 are blue LED chips, which are used to emit blue light having a center wavelength in a range from 445 nm to 475 nm.

The second filling layer 232 may include a second transparent material 2320, and a second phosphor 2322 generally evenly doped in the second transparent material 2320. The second phosphor 2322 is green phosphor, and can be excited by excitation light generated from the second LED chip 231 to emit green light having a center wavelength in a range from 505 nm to 540 nm. The green phosphor can be made of nitride, silicate, or oxide. Alternatively, the second phosphor 2322 may be yellow phosphor, which can be excited by excitation light generated from the second LED chip 231 to emit yellow light having a center wavelength in a range from 550 nm to 590 nm. The yellow phosphor can be made of nitride, silicate, or oxide. It can be understood that in other embodiments, the green phosphor and the yellow phosphor may both be doped in the second transparent material 2320.

The first phosphor 1222 is excited by the blue light generated from the first LED chip 221 to emit red light, and a part of the blue light generated from the first LED chip 221 can be emitted from the first filling layer 122 through the first transparent material 1220. The second phosphor 2322 is excited by the blue light generated from the second LED chip 231 to emit green light and/or yellow light, and a part of the blue light generated from the second LED chip 231 can be emitted from the second filling layer 232 through the second transparent material 2320. The blue light generated from the third

LED chip 241 can be emitted from the third filling layer 242 directly. The currents flowing through the first LED chip 221, the second LED chip 231, and the third LED chip 241 are controlled independently by the first power supply 101, the second power supply 102, and the third power supply 103, respectively, to adjust the color temperature of the red light and green light emitting from the first filling layer 122, the blue light, green light and/or yellow light emitting from the second filling layer 232, and the blue light emitting from the third filling layer 242. Thus, the light outputted by the light emitting diode illuminating apparatus 20 is formed by a mixture of the red light, the green light and the blue light. Such output light can have different colors and/or different CRIs to meet different needs.

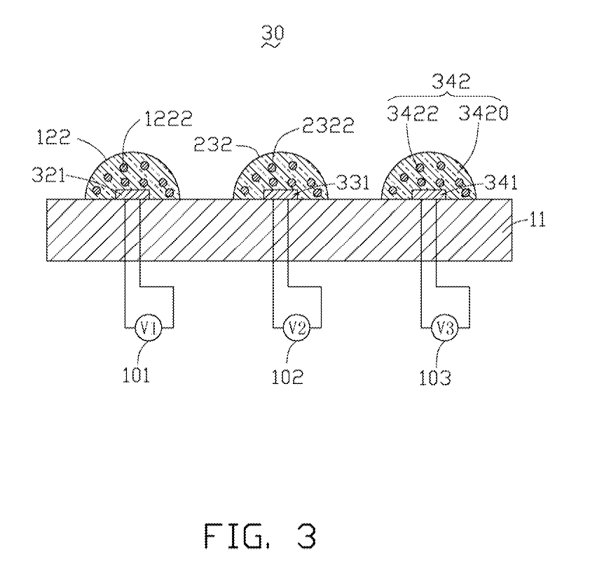

Referring to FIG. 3, a third embodiment of a light emitting diode illuminating apparatus 30 is similar to the second embodiment of the light emitting diode illuminating apparatus 20 except as follows:

A first LED chip 321, a second LED chip 331, and a third LED chip 341 are ultraviolet (UV) LED chips. All the UV LED chips are the same kind. In particular, all the UV LED chips are GaN LED chips or AlGaN LED chips.

A third filling layer 342 may include a third transparent material 3420, and a third phosphor 3422 generally evenly doped in the third transparent material 3420. The third transparent material 3420 may be silicone, resin, or another suitable light-pervious material. The third phosphor 3422 is blue phosphor, and can be excited by excitation light generated from the third LED chip 341 to emit blue light having a center wavelength in a range from 445 nm to 475 nm. The blue phosphor can be made of nitride, silicate, or oxide.

The first phosphor 1222 is excited by the UV light generated from the first LED chip 321 to emit red light. The second phosphor 2322 is excited by the UV light generated from the second LED chip 331 to emit green light and/or yellow light. The third phosphor 3422 is excited by the UV light generated from the third LED chip 341 to emit blue light. The currents flowing through the first LED chip 321, the second LED chip 331, and the third LED chip 341 are controlled independently by the first power supply 101, the second power supply 102, and the third power supply 103, respectively, to adjust the color temperature of the red light emitting from the first filling layer 122, the green light and/or yellow light emitting from the second filling layer 232, and the blue light emitting from the third filling layer 342. Thus, the light output by the light emitting diode illuminating apparatus 30 is formed by a mixture of the red light, the green light and the blue light, or a mixture of the red light, the green light, the blue light and the yellow light. Such output light can have different colors and/or different CRIs to meet different needs.

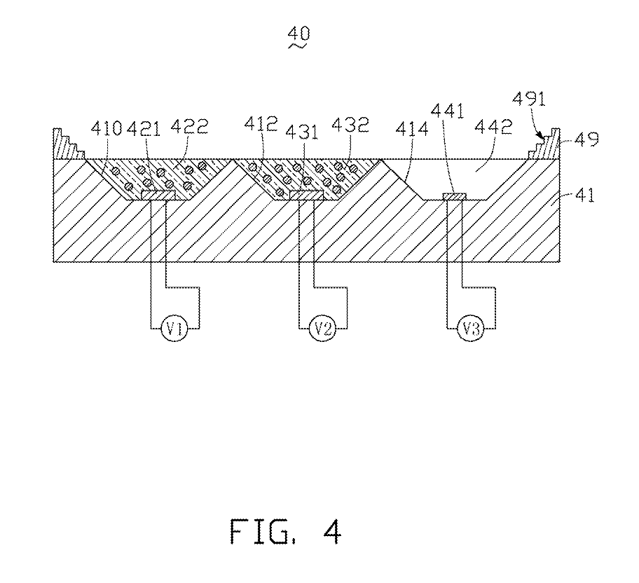

Referring to FIG. 4, a fourth embodiment of a light emitting diode illuminating apparatus 40 is similar to the second embodiment of the light emitting diode illuminating apparatus 20 except as follows:

The light emitting diode illuminating apparatus 40 includes a substrate 41. The substrate 41 has a first recess 410, a second recess 412, and a third recess 414, and the first, second, third recesses 410, 412, 414 are located in a juxtaposed manner Each of the first recess 410, the second recess 412, and the third recess 414 is truncated cone shaped, with a diameter of the truncated cone gradually decreasing from an exposed surface of the substrate 41 thereof. The first LED chip 421, the second LED chip 431, and the third LED chip 441 are positioned on surfaces of the substrate 41 at bottoms of the first recess 410, the second recess 412, and the third recess 414, respectively. The first filling layer 422, the second filling layer 432, and the third filling layer 442 are filled in the first recess 410, the second recess 412, and the third recess 414, respectively.

The first LED chip 421 and the second LED chip 431 are ultraviolet (UV) LED chips. The third LED chip 441 is a blue LED chip. The conversion efficiency of red phosphor which is excited by UV light, is lower than that of other type phosphors, such as green phosphor. Accordingly, the first, second and third LED chips 421, 431, and 441 can be selected to have different sizes, in order to overcome imbalances among the conversion and emission efficiencies between different phosphors. Here, the sizes, such as square/rectangular dimensions of the first and second LED chips 421, 431 (as viewed from above the light emitting diode illuminating apparatus 40) are 1 mm×1 mm, and the size of the third LED chip 441 is 0.6 mm×0.6 mm smaller than that of the first and second LED chips 421, 431.

The light emitting diode illuminating apparatus 40 further includes an annular reflective member 49 positioned on the substrate 41 and generally surrounding the first, second, and third recesses 410, 412, and 414. The light emitted from the first, second, and third filling layers 422, 432, and 442 is reflected by an inner surface 491 of the reflective member 49, so as to help achieve light mixing. Here, the inner surface 491 has a stepped configuration. The reflective member 49 may be made of Polyphthalamide (PPA), Polyamide 9T (PA9T), liquid crystal polymer (LCP), etc.

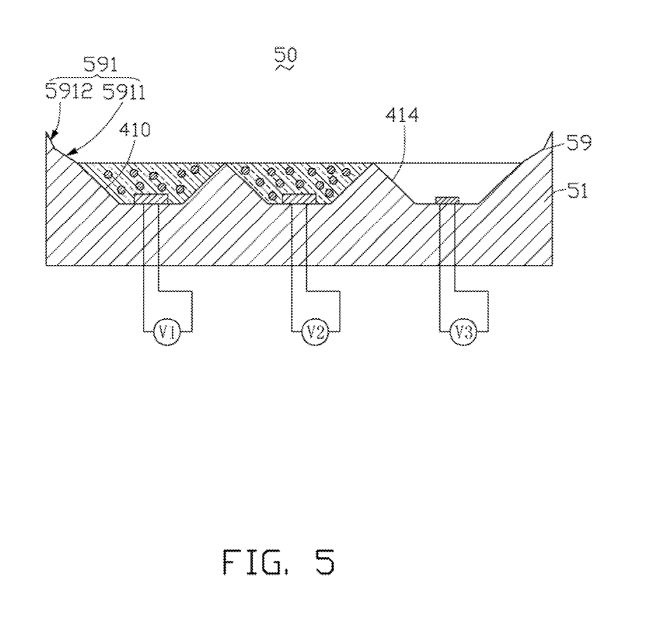

Referring to FIG. 5, a fifth embodiment of a light emitting diode illuminating apparatus 50 is similar to the fourth embodiment of a light emitting diode illuminating apparatus 40 except as follows:

An inner surface 591 of a reflective member 59, which has two consecutive portions with different gradients, includes a first surface portion 5911 close to the first and third recesses 410, 414, and a second surface portion 5912 farther away from the first and third recesses 410, 414. A transverse cross-section of each of the first and second surface portions 5911, 5912 is a straight line. The first surface portion 5911 has a first gradient, and the second surface portion 5912 has a second gradient different from the first gradient. In the illustrated embodiment, the first gradient is less than the second gradient. The reflective member 59 is integrally formed with the substrate 51. That is, the substrate 51 and the reflective member 59 are portions of the one same single body of material. It can be understood that the inner surface 591 may include more than two consecutive portions having different gradients.

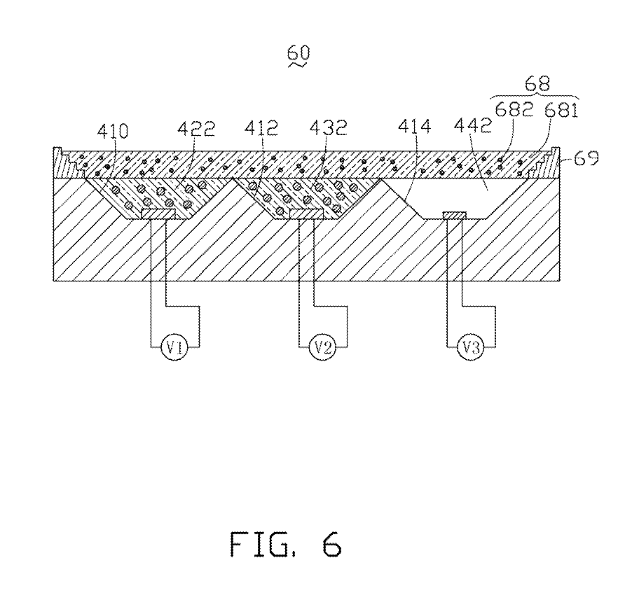

Referring to FIG. 6, a sixth embodiment of a light emitting diode illuminating apparatus 60 is similar to the fourth embodiment of the light emitting diode illuminating apparatus 40 except as follows:

The light emitting diode illuminating apparatus 60 further includes a light scattering layer 68. The light scattering layer 68 is positioned (filled) in the reflective member 69 to cover the first filling layer 422, the second filling layer 432, and the third filling layer 442. The light scattering layer 68 includes a fourth transparent material 681, and a plurality of scattering particles 682 generally evenly distributed in the fourth transparent material 681. The fourth transparent material 681 may be silicone, resin, or another suitable light-pervious material. The refractive index of the fourth transparent material 681 is less than or equal to the refractive index of the transparent materials of the first, the second, and the third filling layer 422, 432, 442. The scattering particles 682 can be made of TiO₂, plastic, polymethyl methacrylate (PMMA), fused silica, aluminum oxide (Al₂O₃), magnesium oxide (MgO, sialon), or another suitable transparent nitrogen oxide. The refractive index of the scattering particles 682 is in a range of 1.1 to 2.4. The scattering particles 682 are configured for scattering the red light, the green and/or yellow light, and the blue light respectively emitting from the first filling layer 422, the second filling layer 432, and the third filling layer 442, so as to improve the uniformity of light output by the light emitting diode illuminating apparatus 60.

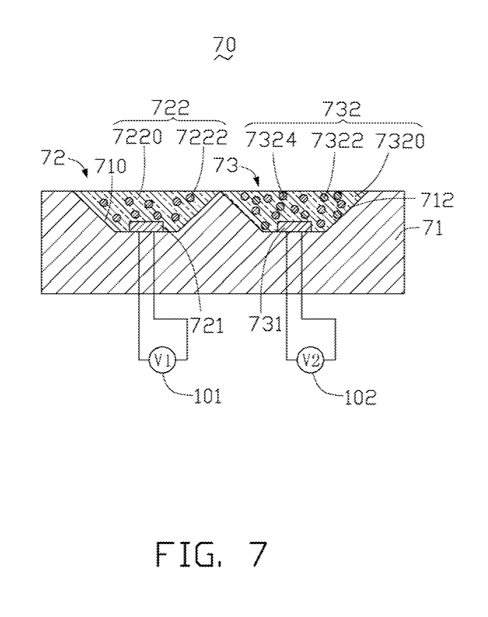

Referring to FIG. 7, a seventh embodiment of a light emitting diode illuminating apparatus 70 includes a substrate 71, a first lighting element 72, and a second lighting element 73.

The substrate 71 defines a first recess 710 and a second recess 712. Each of the first recess 710 and the second recess 712 is truncated cone shaped, with a diameter of the truncated cone gradually decreases from an exposed surface of the substrate 71. The first and second recesses 710, 712 are located in a juxtaposed manner.

The first lighting element 72 includes a first LED chip 721, and a first filling layer 722 encapsulating the first LED chip 721. The second lighting element 73 includes a second LED chip 731, and a second filling layer 732 encapsulating the second LED chip 731. The first LED chip 721 and the second LED chip 731 are positioned at bottoms of the first recess 710 and the second recess 712, respectively, and are electrically connected to the substrate 71. The first filling layer 722 and the second filling layer 732 are positioned (filled) in the first recess 710 and the second recess 712, respectively.

Both the first LED chip 721 and the second LED chip 731 are the same kind of

LED chip. In the present embodiment, both the first and second LED chips 721, 731 are GaN LED chips, AlGaN LED chips, or InGaN LED chips. Here, the first LED chip 721 and the second LED chip 731 are UV chips. Thus, temperature-dependent light attenuation of the first LED chip 721 is essentially the same as that of the second LED chip 731. As a result, color temperature of white light emitted from the light emitting diode illuminating apparatus 70 is stable, and luminous efficiency of the first and second LED chips 721, 731 is also stable. The first LED chip 721 and the second LED chip 731 are electrically connected to a first power supply 101 and a second power supply 102, respectively. The first and second LED chips 721, 731 each include a separate driving circuit. That is, voltages and currents in the first and second LED chips 721, 731 are independently controlled by the first power supply 101 and the second power supply 102, respectively.

The first filling layer 722 includes a first transparent material 7220, and a first phosphor 7222 generally evenly doped in the first transparent material 7220. The first transparent material 7220 may be silicone, resin, or another suitable light-pervious material. The first phosphor 7222 is red phosphor, and can be excited by excitation light generated from the first LED chip 721 to emit red light. A center wavelength of the red light is in a range from 610 nm to 645 nm.

The second filling layer 732 includes a second transparent material 7320, a second phosphor 7322 and a third phosphor 7324. The second and third phosphors 7322, 7324 are each generally evenly doped in the first transparent material 7320. The second phosphor 7322 is green phosphor, and can be excited by excitation light generated from the second LED chip 731 to emit green light having a center wavelength in a range from 505 nm to 540 nm. The third phosphor 7324 is blue phosphor, and can be excited by the excitation light generated from the second LED chip 731 to emit blue light having a center wavelength in a range from 445 nm to 475 nm.

The first phosphor 7222 is excited by UV light generated from the first LED chip 721 to emit red light. The second phosphor 7322 and third phosphor 7324 are excited by UV light generated from the second LED chip 731 to respectively emit green light and blue light. The currents flowing through the first LED chip 721 and the second LED chip 731 are controlled independently by the first power supply 101 and the second power supply 102 respectively, to adjust the color temperature of the red light emitting from the first filling layer 722, and the green light and the blue light emitting from the second filling layer 732. Thus, the light output by the light emitting diode illuminating apparatus 70 is formed by a mixture of the red light, the green light and the blue light. Such output light can have different colors and/or different CRIs to meet different needs.

It can be understood that the first LED chip 721 and the second LED chip 731 may instead be blue LED chips, which are used to emit blue light having a center wavelength in a range from 445 nm to 475 nm.

It is believed that the present embodiments and their advantages will be understood from the foregoing description, and it will be apparent that various changes may be made thereto without departing from the spirit and scope of the embodiments or sacrificing all of its material advantages.

What is claimed is:

1. A light emitting diode illuminating apparatus comprising:
a substrate;
a first lighting element being juxtaposed at the substrate, the first lighting element comprising a first LED chip, and a first filling layer encapsulating the first LED chip, the first filling layer including red phosphor generally evenly doped therein; and
a second lighting element being juxtaposed at the substrate, the second lighting element comprising a second LED chip, and a second filling layer encapsulating the second LED chip, the second filling layer including two different phosphor materials respectively doped therein;
wherein the first LED chip and the second LED chip are the same kind of LED chip selected from the group consisting of GaN LED chips, AlGaN LED chips and InGaN LED chips; light emitted from the first filling layer and the second filling layer is capable of mixing to produce light of a uniform color.

2. The light emitting diode illuminating apparatus of claim 1, wherein the first LED chip and the second LED chip are UV LED chips; the second filling layer comprises at least two of blue phosphor, green phosphor and yellow phosphor generally evenly doped therein.

3. The light emitting diode illuminating apparatus of claim 1, wherein the first LED chip and the second LED chip are blue LED chips; the second filling layer comprises green phosphor and yellow phosphor generally evenly doped therein.

4. The light emitting diode illuminating apparatus of claim 1, wherein the first LED chip and the second LED chip each comprises a separate driving circuit.

5. The light emitting diode illuminating apparatus of claim 1, wherein the substrate comprises a first recess and a second recess located in juxtaposed manner, and the first LED chip and the second LED chip are positioned on surfaces of the substrate at the bottoms of the first recess and the second recess, respectively.

6. The light emitting diode illuminating apparatus of claim 5, further comprising an annular reflective member positioned on the substrate to surround the first and second recesses, and the reflective member has an inner surface to reflect light emitted from the first and second filling layers.

7. The light emitting diode illuminating apparatus of claim 6, wherein the inner surface of the reflective member has a stepped configuration.

8. The light emitting diode illuminating apparatus of claim 6, wherein the inner surface of the reflective member comprises at least two consecutive portions having different gradients.

9. The light emitting diode illuminating apparatus of claim 6, further comprising a light scattering layer positioned in the reflective member to cover the first and second filling layers, wherein the light scattering layer comprises a plurality of scattering particles evenly distributed therein.
